(19) United States
(12) Patent Application Publication
(10) Pub. No.: US 2012/0274349 A1
(43) Pub. Date: Nov. 1, 2012

(54) DEBUG CARD FOR MOTHERBOARD

(75) Inventors: WEN-SEN HU, Shenzhen City (CN); WEI-MIN HE, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/115,989

(22) Filed: May 26, 2011

(30) Foreign Application Priority Data
Apr. 28, 2011 (CN) 201110107893.6

(51) Int. Cl. G01R 31/28

(52) U.S. Cl. 324/763.01

(57) ABSTRACT

A debug card includes a connector, a driving circuit, a switching circuit, and a testing circuit. The connector is connected to an expansion slot of a motherboard. The switching circuit is connected between the connector and the testing circuit to select data channels between the connector and the testing circuit through a low level signal or a high level signal received by a ground pin of the connector. The driving circuit is connected to the connector, the switching circuit, and the testing circuit, to provide voltages to the switching circuit and the testing circuit through the connector and the expansion slot.

### BACKGROUND

1. Technical Field

The present disclosure relates to a debug card for testing a motherboard.

2. Description of Related Art

At present, it is often required to test a motherboard through a debug card during designing of the motherboard. However, it is possible to insert the debug card wrongly and damage the motherboard or the debug card. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a block diagram of a debug card for a motherboard in accordance with an exemplary embodiment of the present disclosure, the debug card includes a driving circuit, a switching circuit, a testing circuit, and a connector.

FIG. 2 is a circuit diagram of the driving circuit of FIG. 1.

FIG. 3 is a circuit diagram of the switching circuit of FIG. 1.

FIG. 4 is a circuit diagram of the testing circuit of FIG. 1.

FIGS. 5 and 6 are schematic diagrams of the connector of FIG. 1 connected to the motherboard.

### DETAILED DESCRIPTION

The disclosure, including the drawings, is illustrated by way of examples and not by limitation. It should be noted that references to “an” or “one” embodiment in this disclosure are not necessarily to the same embodiment, and such references mean at least one.

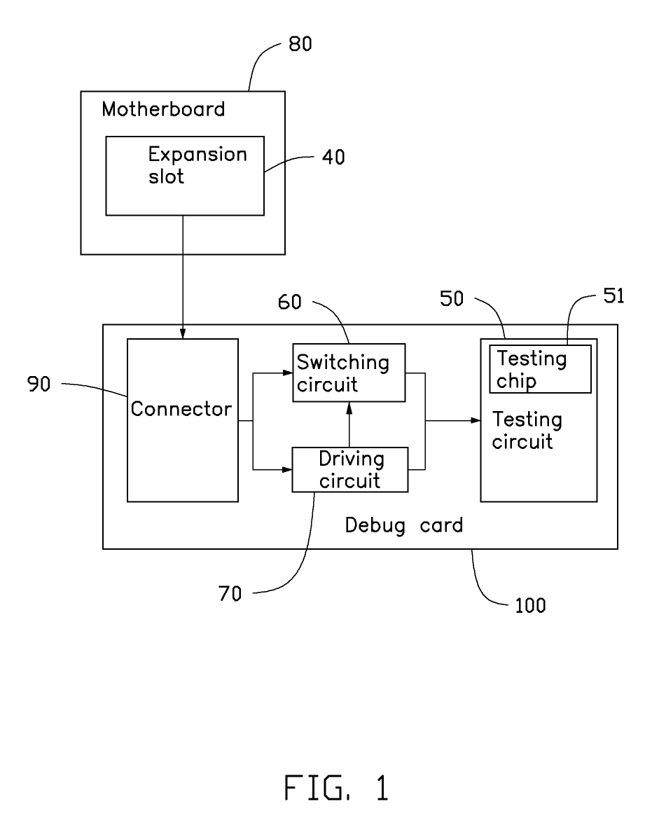

Referring to FIG. 1, a debug card 100 is configured to test a motherboard 80. The debug card 100 in accordance with an exemplary embodiment includes a connector 90, a driving circuit 70, a switching circuit 60, and a testing circuit 50. The connector 90 is connected to the switching circuit 60 and the driving circuit 70. The switching circuit 60 and the driving circuit 70 are both connected to the testing circuit 50. The driving circuit 70 is also connected to the switching circuit 60. The debug card 100 is electrically connected to the motherboard 80 by connector 90 to an expansion slot 40 of the motherboard 80.

The driving circuit 70 receives voltages from the motherboard 80 through the expansion slot 40 and the connector 90, and provides the received voltages to the switching circuit 60 and the testing circuit 50.

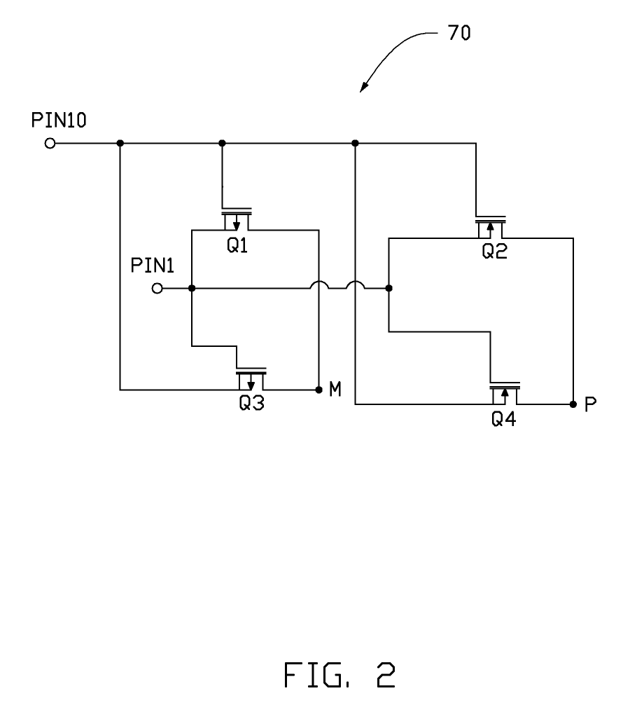

The switching circuit 60 selects data channels for communicating with the motherboard 80 through the connector 90 according to whether a low level signal or a high level signal is received by a ground pin PIN10 (shown in FIG. 2) of the connector 90.

In one embodiment, the testing circuit 50 includes a testing chip 51 for testing the motherboard 80.

Referring to FIG. 2, the driving circuit 70 includes field effect transistors (FETs) Q1-Q4. The FETs Q1 and Q3 are p-channel FETs. The FETs Q2 and Q4 are n-channel FETs. The ground pin PIN10 of the connector 90 interconnects the gate terminals of the FETs Q1 and Q2 and the source terminals of the FETs Q3 and Q4. The drains of the FETs Q1 and Q3 are connected together. A power pin PIN1 of the connector 90 interconnects the sources of the FETs Q1 and Q2 and the gates of the FETs Q3 and Q4. The drains of the FETs Q2 and Q4 are connected together. In other embodiments, the FETs Q1 and Q3 may be pnp transistors, the FETs Q2 and Q4 may be npn transistors.

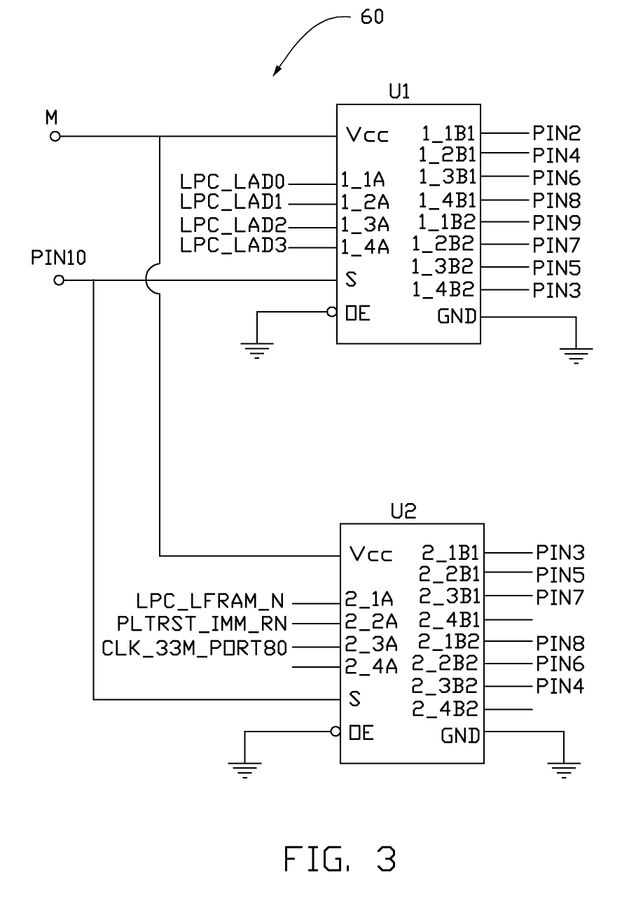

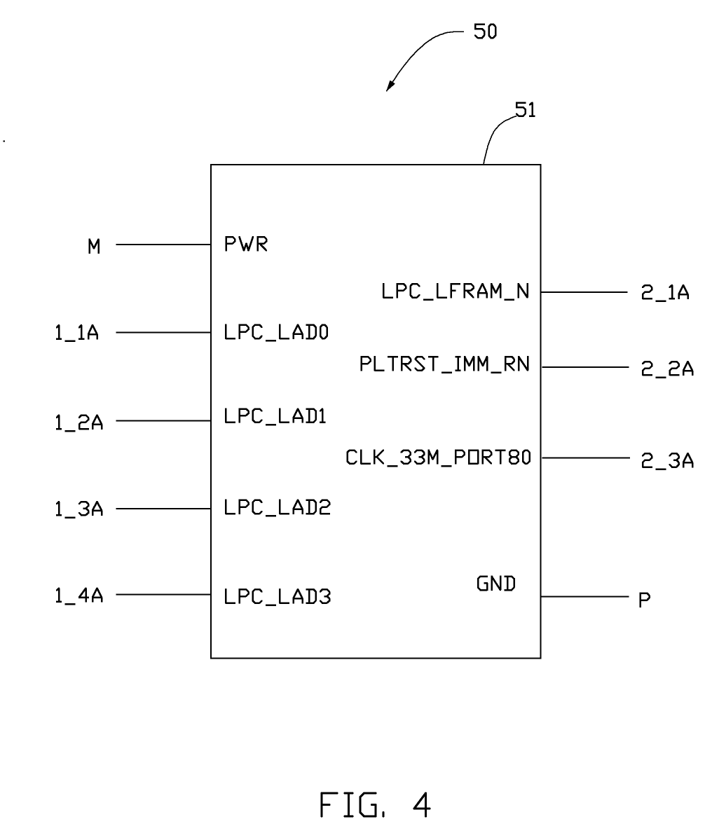

Referring to FIGS. 3 and 4, the switching circuit 60 includes switch chips U1 and U2. In one embodiment, types of the switch chips U1 and U2 may be SSOP16 chips. The voltage pins VCC of the switch chips U1 and U2 are connected to the drains of the FETs Q3 and Q1. Ground pins GND and enable pins OE of the switch chips U1 and U2 are grounded. Control pins S of the switch chips U1 and U2 are connected to the ground pin PIN10 of the connector 90.

Input pins 1_1A, 1_2A, 1_3A, and 1_4A of the switch chip U1 are respectively connected to pins LPC_LAD0, LPC_LAD1, LPC_LAD2, and LPC_LAD3 of the testing circuit 50. Channels 1_B1 and 1_B2 of the switch chip U1 are connected to corresponding pins of the connector 90. The 1_B1 channel includes output pins 1_1B1 to 1_4B1, and the 1_B2 channel includes output pins 1_1B2 to 1_4B2. The output pins 1_1B1, 1_2B1, 1_3B1, and 1_4B1 of the switch chip U1 are respectively connected to pins PIN2, PIN4, PIN6, and PIN8 of the connector 90. The output pins 1_1B2, 1_2B2, 1_3B2, and 1_4B2 of the switch chip U1 are respectively connected to pins PIN9, PIN7, PIN5, and PIN3 of the connector 90.

Input pins 2_1A, 2_2A, and 2_3A of the switch chip U2 are respectively connected to pins LPC_LFRAM_N, PLTRST_IMM_RN, and CLK_33M_PORT80 of the testing circuit 50. An input pin 2_4A of the switch chip U2 is idle. Channels 2_B1 and 2_B2 of the switch chip U2 are connected to corresponding pins of the connector 90. The 2_B1 channel includes output pins 2_1B1 to 2_4B1, and the 2_B2 channel includes output pins 2_1B2 to 2_4B2. The output pins 2_1B1, 2_2B1, and 2_3B1 of the switch chip U2 are respectively connected to the pins PIN3, PIN5, and PIN7 of the connector 90. The output pin 2_4B1 of the switch chip U2 is idle. The output pins 2_1B2, 2_2B2, and 2_3B2 of the switch chip U2 are respectively connected to the pins PIN8, PIN6, and PIN4 of the connector 90. The output pin 2_4B2 of the switch chip U2 is idle. The power pin PWR of the testing circuit 50 is connected to the drains of the FETs Q1 and Q3. The ground pin GND of the testing chip 51 is connected to the drains of the FETs Q2 and Q4.

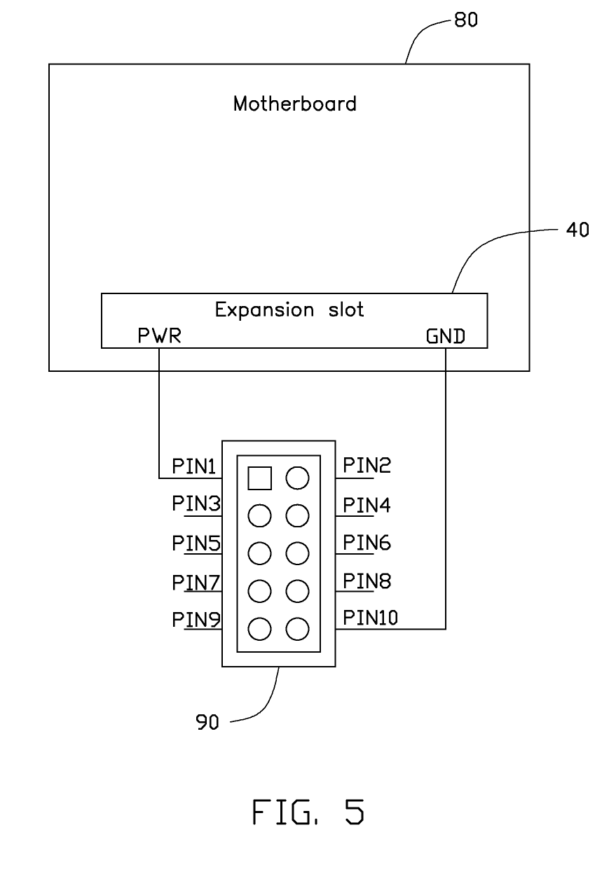

Referring to FIG. 5, if the debug card 100 is inserted into the expansion slot 40 of the motherboard 80 correctly, (namely, the power pin PIN1 and the ground pin PIN10 of the connector 90 are respectively connected to the power pin PWR and the ground pin GND of the expansion slot 40), the power pin PIN1 of the connector 90 receives a high level signal and the ground pin PIN10 of the connector 90 receives a low level signal. The gate of the FET Q1 receives a low level signal and the source of the FET Q1 receives a high level signal. The FET Q1 is turned on. The gate of the FET Q3 receives a high level signal and the source of the FET Q3 receives a low level signal. The FET Q3 is turned off. The motherboard 80 provides voltages to the switch chips U1 and U2 and the testing circuit 50 through the expansion slot 40, the connector 90, and the FET Q1. At the same time, the gate of the FET Q2 receives a low level signal and the source of the FET Q2 receives a high level signal. The FET Q2 is turned off. The gate of the FET Q4 receives a high level signal and the source of the FET Q4 receives a low level signal. The FET Q4 is turned on. The ground pin GND of the testing circuit 50 is connected to the ground pin PIN10 of the connector 90 through the FET Q4. As a result of the ground pin PIN10 of the connector 90 being connected to the ground pin GND of the expansion slot 40 of the motherboard 80, the control pins S of the switch chips U1 and U2 receive low level signals. The 1_B1 channel of the switch chip U1 and the 2_B1 channel of the switch chip U2 are turned on. The 1_B2 of the switch chip U1 and the 2_B2 channel of the switch chip U2 are turned off. Thus, the debug card 100 can communicate with the motherboard 80 through the 1_B1 channel of the switch chip U1 and the 2_B1 channel of the switch chip U2.

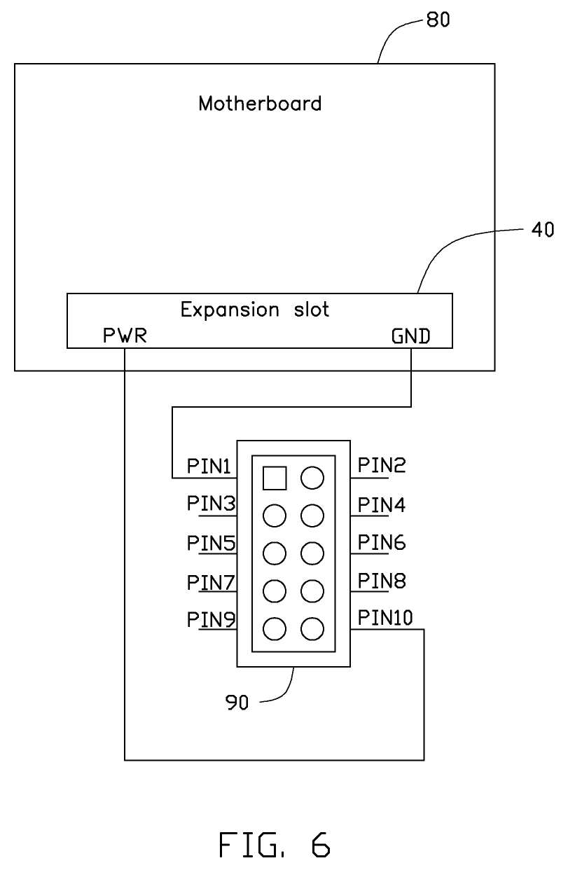

Referring to FIG. 6, if the debug card 100 is inserted into the expansion slot 40 of the motherboard 80 incorrectly, (namely, the power pin PIN1 and the ground pin PIN10 of the connector 90 are respectively connected to the ground pin GND and the power pin PWR of the expansion slot 40), the power pin PIN1 of the connector 90 receives a low level signal and the ground pin PIN10 of the connector 90 receives a high level signal. The gate of the FET Q3 receives a low level signal and the source of the FET Q3 receives a high level signal. The FET Q3 is turned on. The gate of the FET Q1 receives a high level signal and the source of the FET Q1 receives a low level signal. The FET Q1 is turned off. The motherboard 80 provides voltages to the switch chips U1 and U2 and the testing circuit 50 through the expansion slot 40, the connector 90, and the FET Q3. At the same time, the gate of the FET Q4 receives a low level signal and the source of the FET Q4 receives a high level signal. The FET Q4 is turned off. The gate of the FET Q2 receives a high level signal and the source of the FET Q2 receives a low level signal. The FET Q2 is turned on. The ground pin GND of the testing circuit 50 is connected to the power pin PIN1 of the connector 90 through the FET Q2. Due to the ground pin PIN10 of the connector 90 being connected to the power pin PWR of the motherboard 80, the control pins S of the switch chips U1 and U2 receive high level signals. Then, the 1_B2 channel of the switch chip U1 and the 2_B2 channel of the switch chip U2 are turned on. The 1_B1 of the switch chip U1 and the 2_B1 channel of the switch chip U2 are turned off. Thus, the debug card 100 can communicate with the motherboard 80 through the 1_B2 channel of the switch chip U1 and the 2_B2 channel of the switch chip U2.

The debug card 100 can select different channels through the low level signal or high level signal received by the ground pin PIN10 of the connector 90, to further communicate with the motherboard 80 through the selected different channels when the debug card 100 is electrically connected to the motherboard 80.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A debug card for a motherboard, the debug card comprising:
a connector to be connected to an expansion slot of the motherboard;
a testing circuit to test the motherboard;
a switching circuit connected between the connector and the testing circuit, the switching circuit selecting data channels of communication between the connector and the testing circuit through a low level signal or a high level signal received by a ground pin of the connector; and
a driving circuit connected to the connector, the switching circuit, and the testing circuit, the driving circuit providing voltages to the switching circuit and the testing circuit through the connector and the expansion slot.

2. The debug card of claim 1, wherein the connector comprises first to tenth pins, the first pin and the tenth pins are, respectively, a power pin and a ground pin, the first pin is connected to the driving circuit, the tenth pin is connected to the driving circuit and the switching circuit, the second to the ninth pins are connected to the switching circuit.

3. The debug card of claim 2, wherein the driving circuit comprises first to fourth electronic switches, each of the first to the fourth electronic switches comprises first to third terminals, the tenth pin of the connector is connected to the first terminals of the first and the second electronic switches and the second terminals of the third and the fourth electronic switches, the third terminals of the first and the third electronic switches are connected together, the first pin of the connector is connected to the second terminals of the first and the second electronic switches and the first terminals of the third and the fourth electronic switches, the third terminals of the second and the fourth electronic switches are connected together, the switching circuit and the testing circuit are connected to the third terminals of the first and the third electronic switches, the testing circuit is also connected to the third terminals of the second and the fourth electronic switches.

4. The debug card of claim 3, wherein the first and the third electronic switches are p-channel filed effect transistors (FETs), the first to third terminals of the first and the third electronic switches correspond to gates, sources, and drains of the FETs, the second and the fourth electronic switches are n-channel filed effect transistors (FETs), the first to third terminals of the second and the fourth electronic switches correspond to gates, sources, and drains of the FETs.

5. The debug card of claim 3, wherein the testing circuit comprises a testing chip, the testing chip comprises first to ninth pins, the first pin of the testing chip is a power pin connected to the third terminals of the first and the third electronic switches, the ninth pin of the testing chip is a ground pin connected to the third terminals of the second and the fourth electronic switches, the second to eighth pins of the testing chip are data pins connected to the switching circuit.

6. The debug card of claim 5, wherein the switching circuit comprises first and second switch chips, voltage pins of the first and the second switch chips are connected to the third terminals of the first and the third electronic switches, controls pins of the first and the second switch chips are connected to the tenth pin of the connector, first to fourth input pins of the first switch chip are respectively connected to the second to the fifth pins of the testing circuit, first to fourth output pins of the first switch chip are respectively connected to the second pin, the fourth pin, the sixth pin, and the eight pin of the connector, the fifth to eighth output pins of the first switch chip are respectively connected to the ninth pin, the seventh pin, the fifth pin, and the third pin of the connector, first to third input pins of the second switch chip are respectively connected to the sixth to the eighth pins of the testing circuit, the fourth pin of the second switch chip is idle, first to third output pins of the second switch chip are respectively connected to the third pin, the fifth pin, and the seventh pin of the connector, the fourth pin of the second switch is idle, fifth to seventh output pins of the second switch chip are respectively connected to the eighth pin, the sixth pin, and the fourth pin of the connector, an eighth output pin of the second switch chip is idle.
